(19) United States
(12) Patent Application Publication
(10) Pub. No.: US 2008/0012516 A1
(43) Pub. Date: Jan. 17, 2008

(54) Electromotive Furniture Drive

(75) Inventor: Martin Ctvrtnicek, Bunde (DE)

Correspondence Address: Perry Palan, Barnes & Thornburg LLP, 750 17th Street, NW, Washington, DC, 20006, US

(73) Assignee: DEWERT ANTRIEBS- UND SYSTEMTECHNIK GMBH, Kirchlengern (DE)

(21) Appl. No.: 11/767,003

(22) Filed: Jun. 22, 2007

(30) Foreign Application Priority Data
Jun. 28, 2006 (DE) 20 2006 010 135.7

(51) Int. Cl. G01R 31/02

(52) U.S. Cl. 318/490

(57) ABSTRACT

An electromotive furniture drive for adjusting at least one movable component of a piece of furniture, having at least one electric motor for adjusting the movable component, at least one operating device with switching elements for actuating the electric motor, at least one control unit for controlling the at least one electric motor as a function of the operating device, and at least one power supply unit. At least one analyzing device has at least one signaling element for checking the function of the at least one electric motor, of the at least one control unit, of the at least one operating device and of the at least one power supply unit, and has at least one actuating element.

### BACKGROUND AND SUMMARY OF THE DISCLOSURE

The invention relates to an electromotive furniture drive for adjusting at least one movable component of a piece of furniture.

As a rule, such electromotive furniture drives require no maintenance. However, they are subjected to a certain amount of wear during their use. In individual cases, particularly after an extended use, this wear can cause an impairment of functions if a component, for example, the manual operating device, no longer or only to a limited extent has or carries out a desired function as a result of excessively frequent use. Under certain circumstances, such an impairment of functions may involve the function of the entire electromotive furniture drive because the user cannot easily recognize in such a case which one of the components has a defect. A complete system will therefore be exchanged although only one component would have had to be exchanged. This is a disadvantage resulting in corresponding costs with respect to shipment and checking.

One know solution is that electromotive furniture drives, particularly for seating furniture, have been equipped with a visual indicating system which visually signals the action of voltage upon the respective motor. By means of this device, the user can recognize, for example, by the lighting-up of an indicator light in his operating device, whether a signal is emitted during the operation. By means of light sources of another light in the motor line, the user can recognize in this case whether this motor line is also supplied with voltage during the operation. This permits a detection of a defective component in a certain manner.

This construction has been successful. However, a clear limitation for the monitoring of the individual components of the electromotive furniture drive is disadvantageous because, by means of this above-mentioned construction, only the function of the respective electric motor can be checked if the operating device is functioning. In the case of a defective operating device, further investigations with respect to defective components are impossible.

The present system creates an electromotive furniture drive having an analyzing device which no longer has the above-mentioned disadvantages and the corresponding analyzing device.

The present system creates an electromotive furniture drive with an analyzing device which has an actuating element.

In this manner, a user is capable of immediately determining, by the simple actuation of the analyzing device, which one of the components has a defect. This becomes possible irrespective of which components are defective.

In an embodiment, the analyzing device is connected down stream of the power supply unit. Since the involved motors are so-called low-voltage motors, the power supply unit may consists at least of a transformer which reduces the public electric supply system voltage to a voltage with a lower potential.

However, the power supply unit may also have an accumulator, a switched-mode power supply, a voltage transducer or a system-side power supply. In the latter case, the motors may be constructed as system-supplied motors. Furthermore, an input-side system clearing device, an output-side rectifier circuit for generating a direct current and/or an output-side control device having electromechanical switches may be assigned to the power supply unit. In this case, a control device has control paths coming from the manual operation and leading to the respective electric motor.

In an embodiment, at least one actuating element has the function of at least one switching element of the operating device. As a result, a checking of the functions of components of the drive advantageously becomes possible independently of defective components. In this case, an actuating element can be assigned to each switching element of the operating device. It is also conceivable that several switching elements are assigned to the activating element. When the actuating element is operated, a circuit is closed. This may, for example, be at least one control path. The operation of the respective actuating element is equivalent to the switching elements of the operating device. Furthermore, a display, such as a visual display, may also be assigned to the power path, which display emits a light signal as soon as the power path is supplied with voltage. By operating an actuating element, the operator can now check the function of one or more motors, the correct functioning of the power supply unit, of the control unit or of the branching unit and of the operating device independently of a possibly faulty component.

In this case, in which the control unit has power switching elements for switching a power path of the at least one electric motor, it is provided in an embodiment that the at least one actuating element is switched parallel to at least one switching element of the operating device. As a result, the function of the power switching elements of the control unit and of motors connected thereto can be easily checked without an operation of the operating device. For checking the operating device, the latter is operated afterwards, whereby, with the preceding positive checking of the corresponding components, it can easily be determined whether the defect is in the operating device.

Another embodiment provides a control unit having a branching device, in which the analyzing device is integrated. In this case, the power switching elements are arranged in the operating device. This is called a direct switching of the power path of the electric motor because the switches are then arranged in the power path. In this case, in which the at least one switching element of the operating device has a power switching element for switching the power path of the at least one electric motor and the control unit is constructed as a branching unit. In this alternative embodiment that the at least one actuating element has a power switching element for interrupting the power path to the operating device and a power switching element for switching the power path to the at least one electric motor. This results in an expansion of the range of use of the analyzing device.

In another embodiment, the at least one analyzing device is a component of the at least one control unit. As a result, it is permitted that an electromotive furniture drive is equipped with an integrated analyzing device, which allows a simple checking. Individual components, such as the transformer, the accumulator, the switched-mode power supply, the voltage transducer, the rectifier circuit, the analyzing device and the control device may be inserted in a common housing. Individual components or a selection of respective components may also be inserted in a common housing. In this case, the housing may be partially or completely filled, so that an insulating material can be cast around the components.

In another alternative embodiment, the at least one analyzing device is constructed to be mountable on the at least one control unit. In this manner, the analyzing device can be retrofitted. A temporary application is thereby also conceivable.

In another embodiment it is provided that the at least one analyzing device has an evaluation unit. This permits a comfortable checking with a correspondingly simple display, an automated checking also being conceivable.

The analyzing device is electrically connected down stream of the power supply unit. This also advantageously permits the functional testing of this power supply unit. In this case, the analyzing device has its own power supply, for example, a battery, whereby it is advantageously independent of the power supply unit.

An analyzing device having at least one signaling element for testing the function of an electromotive furniture drive and at least one its components are constructed such that the analyzing device has at least one actuating element. In this case, the at least one actuating element has the function of at least one switching element of an operating device of the electromotive drive, thereby allowing a function testing which is close to reality.

In another embodiment, the analyzing device can be built onto the electromotive drive or can be installed in the latter. This results in a broad usage range of the analyzing device.

The device will be explained by the following description of preferred embodiments with reference to the attached drawings.

### BRIEF DESCRIPTION OF THE DRAWINGS

FIG. 1 is a schematic view of a first embodiment of an electromotive furniture drive with a control path and a power path; and

FIG. 2 is a schematic view of a second embodiment of an electromotive furniture drive with a power path.

### DETAILED DESCRIPTION OF THE EMBODIMENTS

The electromotive furniture drive 10 schematically illustrated in this first embodiment consists of several components: An operating device 12 having several switching elements 13, for example, key buttons; an electric motor 18; a power supply unit 14 and a control unit 15. The power supply 14 is to be connected to a public power supply system 11, which may be formed by a plug part having an inserted system clearing device. The power supply unit 14 consists of at least a transformer which can be followed by a rectifier circuit and a filtering device. The switching signals which can be triggered by the respective switching elements 13 of the operating device 12 are fed by way of a control path 16 through a line to the control unit 15. In a manner not shown in detail, electromechanical switches, such as relays, are arranged in the control unit 15, which switches admit a voltage to the power path 17 as soon as a switching element 13 is operated. A series of switching elements 13 are assigned to each electric motor 18 in order to generate signals for both rotating directions of the electric motor 18.

Furthermore, the electromotive furniture drive 10 has an analyzing device 19 which in this example has two actuating elements 21 and one signaling element 22. Here, the analyzing device 19 is arranged inside the control unit 15. Naturally, the analyzing device 19 may also be mounted outside the control unit 15 by means of corresponding contacts and connections or can be removably mounted, for example, by way of a suitable plug-type connection.

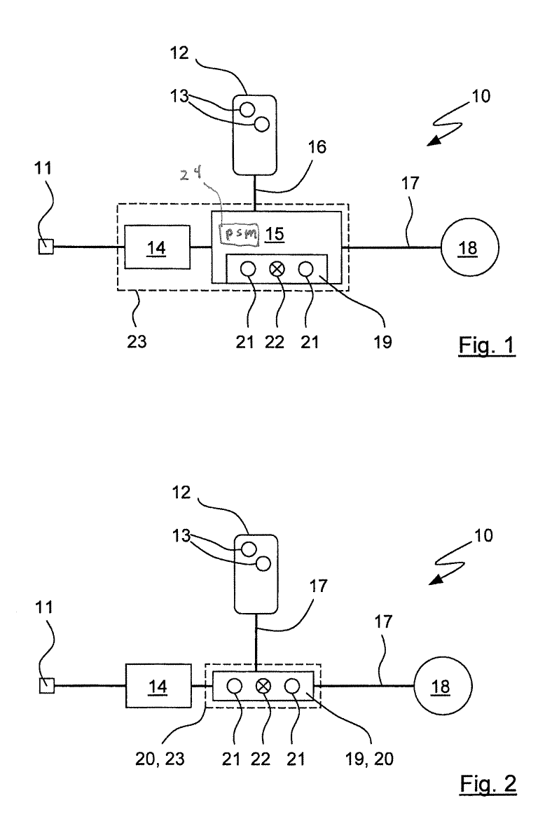

According to FIG. 1, the power supply unit 14 and the control unit 15 and, as required, also the analyzing device 19 may be inserted in a common housing, which is symbolically indicated by position 23.

The analyzing device 19 essentially consists of the actuating elements 21 and of a visual display,—the signaling element 22—which consists at least of a light having at least one indicating color. In a manner not shown in detail, the actuating elements 21 are connected with electrical power switching modules 24 which, in this first embodiment, are switched parallel to the switching elements 13, while the signaling element 22 is switched parallel to the power path 17.

The actuating element 21 is operated for checking functions. The signaling element 22 will then light up because the supply voltage for the electric motor 18 is applied to the output of the control unit 15 to a contact which is not shown. The function of the control unit 15 can thereby be checked. Simultaneously, the connected electric motor 18 has to start unless it is in an end position at the time. In this case, the opposite running direction of the electric motor 18 has to be selected by way of the corresponding actuating element 21 or switching element 13.

After the positive function testing of the electric motor 18, the function of the operating device 12 can be checked, in that the latter is operated, in which case identical functions of the electric motor 18 or of the signaling element 22 have to be triggered.

In the control unit 15, the analyzing device 19 is arranged electrically down stream of the power supply unit 14. If the power supply unit 14 is defective, the analyzing device 19 cannot be actuated, whereby the power supply unit 14 can easily be checked. The analyzing device 19 can also additionally be equipped with its own power supply, such as a battery, whereby, also in the case of a defective power supply unit 14, additional function tests can be carried out. This is particularly advantageous because a defective power supply unit 14 could, under certain circumstances, have triggered another effect, for example, in the operating device 12.

FIG. 2 shows a second embodiment of the electromotive furniture drive 10 which is essentially identical with the embodiment of FIG. 1. In this embodiment, the control unit 15 has no power switching elements but only a branching device 20, so that the control paths 16 do not exist. In a manner not shown in detail, the switching elements 13 directly switch the power path 17 of the electric motor, so that the switching elements 13 are integrated in the circuit of the power path 17. According to the second embodiment according to FIG. 2, the operating device 12, the power supply unit 14 and the respective electric motor 18 are electrically connected with one another by means of the branching unit 20. In this case, for example, the analyzing device 19 may be inserted in a housing 23 of the branching unit 20 or housing parts 23 can be at least partially sprayed around it.

In a manner not shown in detail, the actuating elements 21 and the signaling element 22 are also integrated in the circuit of the power path 17. In this case, the actuating element 21 has a power switching element for interrupting the power path 17 to the operating device 12 and a power switching element for switching the power path 17 to the electric motor 18, because the wiring of the switching elements 13, which is not explained in detail above, in this case, is in series and does not permit a parallel switching with an actuating element 21.

According to FIGS. 1 and 2, all lines or paths are constructed as multi-conductor cables and may have a plug-type contact on at least one end.

The electric motors 18 are indicated symbolically and, in addition to an electric motor 18, may also have mechanical transmissions, for example, in the form of a gearing, a worm gearing, a threaded spindle gearing or combinations thereof.

In a manner not shown in detail, the housing 23 has openings through which the respective actuating element 21 can be operated, and the respective signaling element 22 can be inspected. For this purpose, the actuators of the respective actuating elements 21 can end with the surface of the housing 23 or can be arranged to be set back toward interior.

The invention is not limited to the explained embodiments but can be modified in multiple manners.

Thus, for example, the analyzing device 19 may have an evaluating unit (not shown) which can permit an automatic checking and indicating.

The analyzing device 19 may also have electronic components, such as semiconductor switches, and additional power switching elements, such as relays, for checking the function of components.

1. An electromotive furniture drive for adjusting at least one movable component of a piece of furniture, comprising
at least one electric motor for adjusting the movable component,
at least one operating device with switching elements (13) for actuating the at least one electric motor,
at least one control unit for controlling the at least one electric motor as a function of the at least one operating device,
at least one power supply unit for the electric supply of the control unit,
at least one analyzing device having at least one signaling element for checking the function of the at least one electric motor, of the at least one control unit, of the at least one operating device and of the at least one power supply unit (, and
the analyzing device having at least one actuating element.

2. The electromotive furniture drive according to claim 1, wherein the at least one actuating element has the function of at least one switching element of the operating device.

3. The electromotive furniture drive according to claim 2, wherein the control unit has power switching elements for switching a power path of the at least one electric motor, and the at least one actuating element is switched parallel to the at least one switching element of the operating device by the power switching elements.

4. The electromotive furniture drive according to claim 2, wherein the at least one switching element of the operating device has a power switching element for switching a power path of the at least one electric motor, the control unit is constructed as a branching unit (, the at least one actuating element has a power switching element for interrupting the power path to the operating device and a power switching element for switching the power path to the at least one electric motor.

5. The electromotive furniture drive according to claim 1, wherein the at least one analyzing device is a component of the at least one control unit.

6. The electromotive furniture drive according to claim 1, wherein the at least one analyzing device is constructed to be mountable on the at least one control unit.

7. The electromotive furniture drive according to claim 1, wherein the at least one analyzing device (has an evaluating unit.

8. The electromotive furniture drive according to claim 1, wherein the at least one analyzing device is electrically connected done stream of the power supply unit.

9. The electromotive furniture drive according to claim 1, wherein the at least one analyzing device has its own power supply.

10. An analyzing device comprising: at least one signaling element for the function testing of an electromotive furniture drive and of at least one component of the electromotive furniture drive; and at least one actuating element.

11. The analyzing device according to claim 10, wherein the at least on actuating element has the function of at least one switching element of an operating device of the electromotive furniture drive.

12. The analyzing device according to claim 10, wherein the analyzing device is constructed to be one of built onto and installed in the electromotive furniture drive.
